(19) United States
(12) Patent Application Publication
(10) Pub. No.: US 2025/0211139 A1
(43) Pub. Date: Jun. 26, 2025

(54) CONTINUOUS ENERGY GENERATION APPARATUS USING LIQUID

(71) Applicant: KOREA ELECTRONICS TECHNOLOGY INSTITUTE, Seongnam-si (KR)

(72) Inventor: Soon Hyung KWON, Seongnam-si (KR)

(73) Assignee: KOREA ELECTRONICS TECHNOLOGY INSTITUTE, Seongnam-si (KR)

(21) Appl. No.: 18/984,027

(22) Filed: Dec. 17, 2024

(30) Foreign Application Priority Data
Dec. 20, 2023 (KR) 10-2023-0187585

(51) Int. Cl. H02N 11/00

(52) U.S. Cl. CPC H02N 11/002

(57) ABSTRACT

Disclosed is a continuous energy generation apparatus using liquid including an energy conversion block, which includes a liquid storage module configured to at least temporarily store liquid, a droplet formation module provided with a plurality of nozzles to transform the liquid stored in the liquid storage module into droplets and drop the droplets, and an energy conversion module provided with a plurality of energy conversion devices to output electrical energy through contact with the falling droplets. Because one falling droplet enables production of energy multiple times while passing through the plurality of energy conversion devices, energy is efficiently produced using the droplet.

### CROSS REFERENCE TO RELATED APPLICATION

This patent document claims the priority and benefits of Korean Patent Application No. 10-2023-0187585, filed Dec. 20, 2023, the entire contents of which are incorporated herein by reference for all purposes.

### TECHNICAL FIELD

The present disclosure relates to a continuous energy generation apparatus using liquid.

### BACKGROUND

Devices capable of generating energy using liquid are being developed. There are devices that use temporary charge transfer occurring when a falling droplet contacts and passes through the devices as energy. These devices output energy once when one droplet falls. Thus, energy output may be used once per falling droplet.

Meanwhile, general devices that generate electrical energy may continuously output direct current or alternating current. The continuously output electrical energy facilitates operation of a load. In addition, the continuously output electrical energy is easy to store in a battery. However, because a device for generating energy using liquid outputs electrical energy discretely and outputs electrical energy once per droplet, it is difficult to use the electrical energy for operation of ordinary loads or charging of batteries.

### SUMMARY

The present disclosure provides a multilayer energy conversion module structure capable of generating energy multiple times using one droplet.

In accordance with an aspect of the present disclosure, a continuous energy generation apparatus using liquid includes an energy conversion block, which includes a liquid storage module configured to at least temporarily store liquid, a droplet formation module provided with a plurality of nozzles to transform the liquid stored in the liquid storage module into droplets and drop the droplets, and an energy conversion module provided with a plurality of energy conversion devices to output electrical energy through contact with the falling droplets.

According to an embodiment, the continuous energy generation apparatus using liquid may further include a plurality of energy conversion blocks, each of which includes the liquid storage module, the droplet formation module, and the energy conversion module grouped into a block. The plurality of energy conversion blocks may be stacked vertically so that the droplets used in the energy conversion module of an upper energy conversion block enters the liquid storage module of a lower energy conversion block.

According to an embodiment, the continuous energy generation apparatus using liquid may further include an energy collection unit configured to receive electrical energy output from the plurality of energy conversion devices, convert a discrete flow of energy output from the plurality of energy conversion devices into a continuous flow of energy, and supply the continuous flow of energy to a battery or a load.

According to an embodiment, the energy conversion block may include a plurality of energy conversion modules stacked vertically, and the droplets used in an energy conversion module located at a higher position may fall to an energy conversion module located at a lower position and may be used again to generate energy.

According to an embodiment, the energy conversion block may be configured such that one or more energy conversion modules selected from among a first capacity energy conversion module configured to generate output of a first capacity and a second capacity energy conversion module configured to generate output of a second capacity are stacked vertically, thereby meeting an energy output requirement.

According to an embodiment, the droplet formation module may include one or more nozzles selected from among a first nozzle configured to form a droplet having a first size and a second nozzle configured to form a droplet having a second size.

According to an embodiment, the liquid storage module may include a bottom surface at least partially concavely formed. Among the plurality of nozzles of the droplet formation module, a nozzle connected to a concave portion of the liquid storage module may be formed to have a relatively short length, and a nozzle connected to another portion of the liquid storage module may be formed to have a relatively long length, whereby tips of the plurality of nozzles are located on the same line.

According to an embodiment, the energy conversion block may include one or more energy conversion modules selected from among an independent-type energy conversion module configured such that the plurality of energy conversion devices outputs electrical energy independently and an integrated-type energy conversion module configured such that the plurality of energy conversion devices is integrated with each other to output electrical energy.

According to an embodiment, the continuous energy generation apparatus using liquid may further include a droplet guide module disposed between the plurality of energy conversion modules stacked vertically to guide a direction of the droplets falling from the energy conversion module.

According to an embodiment, the droplet guide module may be formed, based on the placement of the energy conversion devices of an energy conversion module disposed thereabove and the placement of the energy conversion devices of an energy conversion module disposed therebelow, to guide the droplets falling from end points of upper energy conversion devices to fall to start points of lower energy conversion devices.

According to an embodiment, the droplet guide module may include a first droplet guide module formed to guide the droplets in a first direction and a second droplet guide module formed to guide the droplets in a second direction, and the first droplet guide module and the second droplet guide module may be alternately disposed.

According to an embodiment, the plurality of energy conversion modules may be disposed such that the direction of energy conversion devices disposed at a higher position and the direction of energy conversion devices disposed at a lower position are opposite each other so that droplets falling from end points of the energy conversion devices disposed at a higher position fall to start points of the energy conversion devices disposed at a lower position.

The features and advantages of the present disclosure will become more obvious from the following detailed description provided with reference to the accompanying drawings.

Before explaining embodiments of the present disclosure, it is to be understood that the phraseology and terminology used in the following specification and appended claims should not be construed as limited to general and dictionary meanings but be construed as having meanings and concepts according to the spirit of the present disclosure on the basis of the principle that the inventor is permitted to define appropriate terms for the best explanation.

### BRIEF DESCRIPTION OF THE DRAWINGS

The above and other objects, features, and other advantages of the present disclosure will be more clearly understood from the following detailed description taken in conjunction with the accompanying drawings, in which:

FIG. 1 is a view showing a continuous energy generation apparatus using liquid according to an embodiment;

FIG. 2 is a view explaining a form in which three energy conversion blocks are stacked vertically according to an embodiment;

FIG. 3 is a view explaining movement of a droplet in a form in which three energy conversion blocks are stacked vertically according to an embodiment;

FIG. 4 is a view showing an energy conversion device according to an embodiment;

FIG. 5 is a view showing an energy conversion block including a plurality of energy conversion modules according to an embodiment;

FIG. 6 is a view explaining an energy conversion block in which energy conversion modules for each capacity are selectively combined according to an embodiment;

FIG. 7 is a view showing a droplet formation module forming droplets having different sizes according to an embodiment;

FIG. 8 is a view showing a liquid storage module having a concave bottom surface and a droplet formation module provided with nozzles having adjusted lengths;

FIG. 9 is a view showing an energy conversion module in which energy conversion devices are provided in an independent form and an energy conversion module in which energy conversion devices are provided in an integrated form according to an embodiment;

FIG. 10 is a view showing a droplet guide module according to an embodiment; and

FIG. 11 is a view showing an energy conversion module in which the direction of the energy conversion device is adjusted according to an embodiment.

### DETAILED DESCRIPTION

Hereinafter, exemplary embodiments of the present disclosure will be described in detail with reference to the accompanying drawings. However, the exemplary embodiments of the present disclosure to be described below are provided by way of example, and the present disclosure is not limited to the exemplary embodiments set forth herein.

In assigning reference numerals to components in the drawings, it should be noted that identical components are assigned the same reference numerals wherever possible even though they are depicted in different drawings, and similar components are assigned similar reference numerals.

Terms used to describe an embodiment of the present disclosure are not intended to limit the disclosure. It should be noted that singular forms include plural forms as well unless the context clearly indicates otherwise.

In the drawings, components may be exaggerated in size, omitted, or schematically illustrated for convenience in description and clarity. It will be further understood that the terms “have,” “may have,” “include,” and/or “may include,” when used herein, specify the presence of the stated feature (e.g., a numerical value, function, operation, or component such as a part), but do not preclude the presence or addition of one or more other features.

Terms such as “one”, “other”, “another”, “first”, “second”, etc. are used herein to distinguish one component from another component, and the components are not limited by these terms.

Terms indicating directions, such as up, down, left, right, X-axis, Y-axis, Z-axis, etc. are only for convenience of explanation, and it should be understood that these terms may be expressed differently depending on the location of the observer or the location of the object.

The embodiments described herein and the accompanying drawings are not intended to limit the disclosure to specific embodiments. The present disclosure should be understood to include various modifications, equivalents, and/or alternatives to the embodiments.

Hereinafter, embodiments of the present disclosure will be described in detail with reference to the accompanying drawings.

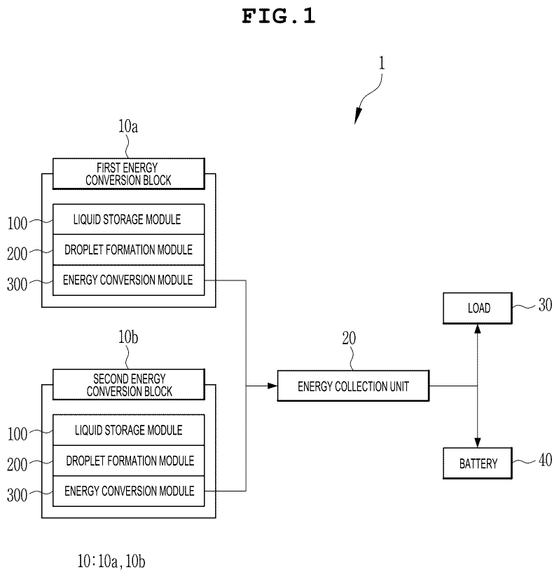

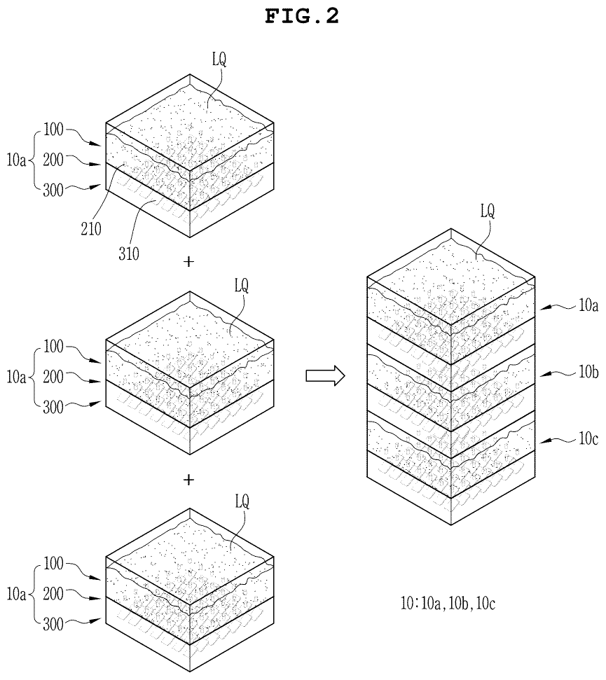

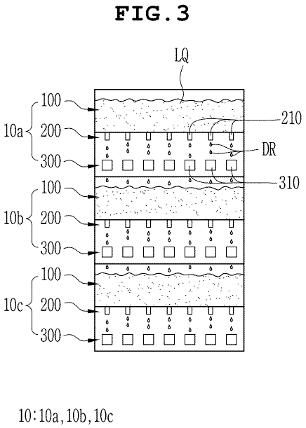

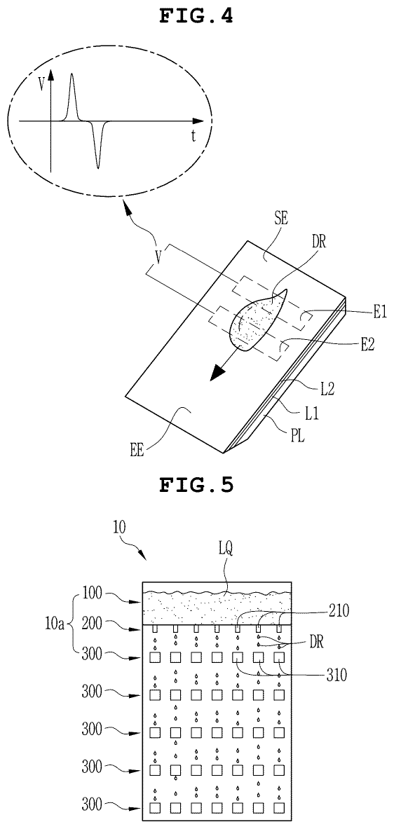

FIG. 1 is a view showing a continuous energy generation apparatus 1 using liquid according to an embodiment. FIG. 2 is a view explaining a form in which three energy conversion blocks 10 are stacked vertically according to an embodiment. FIG. 3 is a view explaining movement of a droplet DR in a form in which three energy conversion blocks 10 are stacked vertically according to an embodiment. FIG. 4 is a view showing an energy conversion device 310 according to an embodiment. FIG. 1, FIG. 2, FIG. 3, and FIG. 4 will be referred to together herein.

The continuous energy generation apparatus 1 using liquid according to an embodiment may include an energy conversion block 10, which includes a liquid storage module 100 that at least temporarily stores liquid LQ, a droplet formation module 200 provided with a plurality of nozzles 210 that transform the liquid LQ stored in the liquid storage module 100 into droplets DR and drop the droplets DR, and an energy conversion module 300 provided with a plurality of energy conversion devices 310 that output electrical energy through contact with the falling droplets DR.

The continuous energy generation apparatus 1 using liquid may further include an energy collection unit 20 that receives electrical energy output from the plurality of energy conversion devices 310, converts a discrete flow of energy output from the energy conversion devices 310 into a continuous flow of energy, and supplies the continuous flow of energy to a battery 40 or a load 30.

The energy conversion block 10 may output energy generated by contact between the falling droplets DR and the energy conversion devices 310. The energy collection unit 20 may collect electrical energy output discretely from the energy conversion devices 310, may convert the discrete flow of electrical energy into a continuous flow of electrical energy, and then may supply the continuous flow of electrical energy to the load 30 or charge the battery 40 with the continuous flow of electrical energy.

The continuous energy generation apparatus 1 using liquid according to the embodiment may include a plurality of energy conversion blocks 10, each of which includes the liquid storage module 100, the droplet formation module 200, and the energy conversion module 300 grouped into a block. The plurality of energy conversion blocks 10 may be stacked vertically, and thus the droplet DR used in the energy conversion module 300 of the upper energy conversion block 10 enters the liquid storage module 100 of the lower energy conversion block 10. Accordingly, one droplet DR may enable production of energy multiple times.

The plurality of energy conversion blocks 10 may include a first energy conversion block 10a and a second energy conversion block 10b. The energy conversion blocks 10 may further include a third energy conversion block 10c. A greater number of energy conversion blocks 10 may be stacked vertically.

The first energy conversion block 10a may include a liquid storage module 100, a droplet formation module 200, and an energy conversion module 300. Identically to the first energy conversion block 10a, the second energy conversion block 10b may include a liquid storage module 100, a droplet formation module 200, and an energy conversion module 300. In the first energy conversion block 10a, the liquid storage module 100 may be located at the top position, the droplet formation module 200 may be located below the liquid storage module 100, and the energy conversion module 300 may be located below the droplet formation module 200. The second energy conversion block 10b may be located below the first energy conversion block 10a. The liquid storage module 100 of the second energy conversion block 10b may be located below the energy conversion module 300 of the first energy conversion block 10a. In the second energy conversion block 10b, the droplet formation module 200 may be located below the liquid storage module 100, and the energy conversion module 300 may be located below the droplet formation module 200.

The liquid LQ supplied to the liquid storage module 100 of the first energy conversion block 10a may be transformed into a droplet DR in the droplet formation module 200, and the droplet DR may fall to the energy conversion device 310 of the energy conversion module 300 so that the energy conversion device 310 generates energy, and then may enter the liquid storage module 100 of the second energy conversion block 10b. Subsequently, the liquid LQ supplied to the liquid storage module 100 of the second energy conversion block 10b may be transformed into a droplet DR in the droplet formation module 200, and the droplet DR may fall to the energy conversion device 310 of the energy conversion module 300 so that the energy conversion device 310 generates energy. If the third energy conversion block 10c is present below the second energy conversion block 10b, the droplet DR may enable continuous generation of energy.

The energy collection unit 20 may include a rectifier circuit, a booster circuit, and various other circuits. The energy collection unit 20 may receive electrical energy output discretely from the plurality of energy conversion devices 310 included in the energy conversion module 300, and may convert the discretely output electrical energy into a continuous flow of electrical energy. The energy collection unit 20 may supply the collected electrical energy to the load 30 or may charge the battery 40 with the collected electrical energy.

As shown in FIG. 2, the plurality of energy conversion blocks 10 may be formed in the same structure, and may be stacked vertically. If three energy conversion blocks 10 are stacked vertically, energy may be generated three times through one droplet DR. If tens or hundreds of energy conversion blocks 10 are stacked vertically, electrical energy may be generated very many times through one droplet DR. Thus, a large amount of electrical energy may be produced in an apparatus having a relatively small volume.

The energy conversion module 300 may include a plurality of energy conversion devices 310. The plurality of energy conversion devices 310 may be arranged in predetermined rows and columns.

The liquid storage module 100, the droplet formation module 200, and the energy conversion module 300 may be accommodated in one case. The modules may be accommodated in the case in a sliding manner. The case may have compartments formed therein so as to accommodate the liquid storage module 100, the droplet formation module 200, and the energy conversion module 300, respectively.

Each of the liquid storage module 100, the droplet formation module 200, and the energy conversion module 300 may have a coupling portion including a protrusion and a recess, whereby the modules 100, 200, and 300 may be stably and fixedly stacked vertically. For example, the coupling portion formed on the lower end of the liquid storage module 100 and the coupling portion formed on the upper end of the droplet formation module 200 may be engaged with each other.

As shown in FIG. 3, the liquid storage module 100 may at least temporarily store the liquid LQ. The liquid LQ stored in the liquid storage module 100 may flow to the droplet formation module 200.

The droplet formation module 200 may include a plurality of nozzles 210. The plurality of nozzles 210 may be connected to the bottom surface BS of the liquid storage module 100 to receive the liquid LQ stored in the liquid storage module 100, and may output the liquid LQ in the form of a droplet DR.

The energy conversion devices 310 of the energy conversion module 300 may be disposed below the nozzles 210 of the droplet formation module 200. The nozzles 210 and the energy conversion devices 310 may be disposed in one-to-one correspondence. Each of the energy conversion devices 310 may be disposed at a point to which one droplet DR falls from a corresponding one of the nozzles 210. If each of the nozzles 210 is formed to generate two or more droplets DR, the energy conversion devices 310 may be disposed at respective points to which the two or more droplets DR fall.

The distance between the nozzle 210 and the energy conversion device 310 may be set to be as short as possible taking into consideration the falling speed of the droplet DR. It is desirable to set the distance between the nozzle 210 and the energy conversion device 310 to be as short as possible, so long as it is possible to secure a speed at which the falling droplet DR is capable of passing through the energy conversion device 310. As the vertical height of the energy conversion block 10 decreases, the number of energy conversion blocks 10 capable of being stacked in a limited space may increase. Therefore, the amount of electrical energy produced may increase.

As shown in FIG. 4, the energy conversion device 310 provided in the energy conversion module 300 may be disposed in an inclined state so that the droplet DR falling thereto flows therealong. The droplet DR falling to a start point SE of the energy conversion device 310 may flow along the inclined surface of the energy conversion device 310, and may finally reach an end point EE of the energy conversion device 310.

The energy conversion device 310 may include a plate PL and two or more electrodes formed on the plate PL. When the droplet DR passes through the electrodes formed on the plate PL, temporary charge transfer may occur. The charge may be transferred to the outside through the electrodes, whereby electrical energy may be output. The first electrode E1 and the second electrode E2 connected to the plate PL may be formed on different surfaces of the plate PL. The first electrode E1 and the second electrode E2 may be formed on the same surface of the plate PL. The first electrode E1 and the second electrode E2 may be formed of different materials. The energy conversion device 310 may include three or more electrodes.

A first layer L1 on which the first electrode E1 and the second electrode E2 are formed may be formed on one surface of the plate PL, and a protective layer L2 may be formed on the first layer L1 in order to protect the first electrode E1 and the second electrode E2.

The energy conversion device 310 may include any of various types of elements having a structure different from the above-described structure or capable of generating energy using a droplet DR in an operation manner different from the above-described operation manner.

FIG. 5 is a view showing an energy conversion block 10 including a plurality of energy conversion modules 300 according to an embodiment.

The energy conversion block 10 according to the embodiment may be configured such that a plurality of energy conversion modules 300 is stacked vertically so that the droplet DR used in an energy conversion module 300 located at a higher position falls to an energy conversion module 300 located at a lower position and is used again to generate energy.

The energy conversion block 10 shown in FIGS. 1, 2, and 3 has a structure including one energy conversion module 300. The energy conversion block 10 shown in FIG. 5 has a structure in which a plurality of energy conversion modules 300 is stacked vertically. The energy conversion block 10 shown in FIG. 5 may include one liquid storage module 100, one droplet formation module 200, and a plurality of energy conversion modules 300. The energy conversion block 10 shown in FIG. 5 may also be provided in plural, and the plurality of energy conversion blocks 10 may be stacked vertically, as shown in FIGS. 1, 2, and 3.

The plurality of energy conversion blocks 10 may be disposed so as to be stacked vertically. The droplet DR used in an energy conversion block 10 located at a higher position may fall to an energy conversion block 10 located at a lower position and may be used again to generate energy. If a plurality of energy conversion modules 300 is disposed vertically in one energy conversion block 10, the size of a space occupied by the liquid storage module 100 or the droplet formation module 200 may be minimized, and thus the amount of energy output per volume may increase.

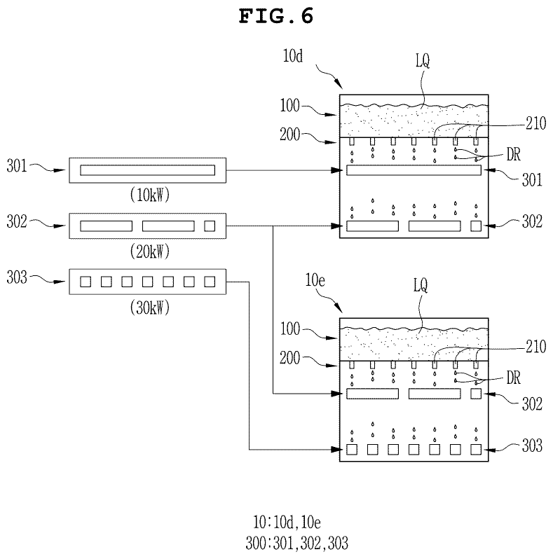

FIG. 6 is a view explaining an energy conversion block 10 in which energy conversion modules 300 for each capacity are selectively combined according to an embodiment.

The energy conversion block 10 may be configured such that one or more energy conversion modules selected from among a first capacity energy conversion module 301 configured to generate output of a first capacity and a second capacity energy conversion module 302 configured to generate output of a second capacity are stacked vertically, thereby meeting an energy output requirement. The energy conversion block 10 may include a third capacity energy conversion module 303, or may include energy conversion modules 300 for various other capacities.

The energy conversion block 10 may be configured such that a plurality of energy conversion modules 300 outputting the determined amounts of power is combined with each other. The first capacity energy conversion module 301, the second capacity energy conversion module 302, and the third capacity energy conversion module 303 may have different capacities. For example, the first capacity may be 10 KW, the second capacity may be 20 kW, and the third capacity may be 30 kW.

The energy capacity required may vary depending on the purpose for which the energy conversion block 10 is used. If the energy capacity required for a certain purpose is 30 kW, the first capacity energy conversion module 301 of 10 KW and the second capacity energy conversion module 302 of 20 kW may be combined with each other vertically, thereby constituting an energy conversion block 10d having a capacity of 30 kW. In another example, if the energy capacity required for a certain purpose is 50 kW, the second capacity energy conversion module 302 of 20 kW and the third capacity energy conversion module 303 of 30 kW may be combined with each other vertically, thereby constituting an energy conversion block 10e having a capacity of 50 kW.

Two first capacity energy conversion modules 301 of 10 kW may be stacked vertically to constitute an energy conversion block 10 having a capacity of 20 kW. In this case, however, the volume may increase compared to a structure including only one second capacity energy conversion module 302 of 20 kW. An energy conversion module 300 having an appropriate capacity may be selected in consideration of the purpose and allowable volume of the energy conversion block 10 and the price and lifespan of the energy conversion module 300.

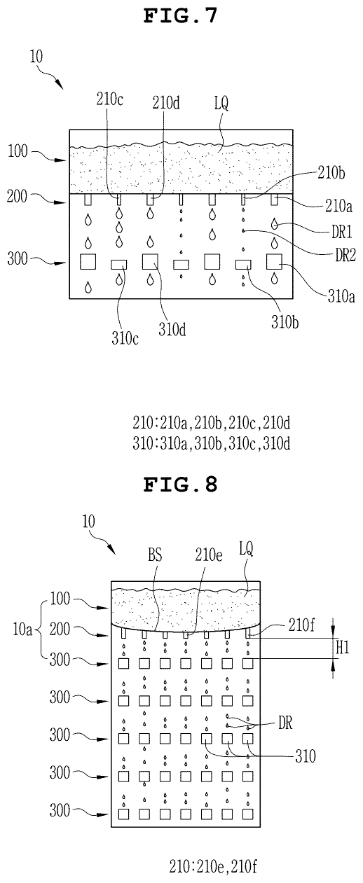

FIG. 7 is a view showing a droplet formation module 200 forming droplets DR having different sizes according to an embodiment.

The droplet formation module 200 according to an embodiment may include one or more nozzles selected from among a first nozzle 210a forming a droplet DR1 having a first size and a second nozzle 210b forming a droplet DR2 having a second size.

The nozzles 210 included in the droplet formation module 200 may include nozzles 210 having various sizes in order to form droplets DR having various sizes. In the droplet formation module 200, a first nozzle 210a forming a droplet DR1 having a first size and a second nozzle 210b forming a droplet DR2 having a second size may be alternately disposed. The droplet formation module 200 may further include a third nozzle forming a droplet having a third size.

The first nozzle 210a and the second nozzle 210b may output droplets DR having different sizes from each other. Alternatively, the first nozzle 210a and the second nozzle 210b may drop the droplets DR at different time intervals from each other. For example, the first nozzle 210a may drop one droplet DR every two seconds, and the second nozzle 210b may drop one droplet DR every three seconds. In this way, the droplets DR output from the plurality of nozzles 210 included in the droplet formation module 200 may have different sizes or may fall at different time intervals.

If the sizes or falling intervals of the droplets DR differ from each other, the energy conversion devices 310, with which the droplets DR come into contact, may have different sizes or inclinations. The energy conversion device 310a, with which the droplet DR1 having a relatively large size comes into contact, may be formed to have a relatively large size, and the energy conversion device 310b, with which the droplet DR2 having a relatively small size comes into contact, may be formed to have a relatively small size. The energy conversion device 310c disposed below the nozzle 210c that drops the droplet DR at a relatively short time interval may be disposed such that the inclination thereof is relatively large, and the energy conversion device 310d disposed below the nozzle 210d that drops the droplet DR at a relatively long time interval may be disposed such that the inclination thereof is relatively small.

FIG. 8 is a view showing a liquid storage module 100 having a concave bottom surface BS and a droplet formation module 200 provided with nozzles 210 having adjusted lengths.

The liquid storage module 100 according to the embodiment may be formed such that at least a portion of the bottom surface BS thereof is concave downward, i.e., in the direction of gravity. The droplet formation module 200 according to the embodiment may be formed such that nozzles 210 connected to the concave portion of the liquid storage module 100 have a relatively short length and nozzles 210 connected to the other portion of the liquid storage module 100 have a relatively long length so that the tips of the nozzles 210 are located on the same line.

A portion of the bottom surface BS of the liquid storage module 100 may be concavely formed. Although it is illustrated in FIG. 8 that the entire area of the bottom surface BS of the liquid storage module 100 is concavely formed with respect to the center thereof, the disclosure is not limited thereto. In another embodiment, a plurality of concave portions may be formed in the bottom surface BS of the liquid storage module 100.

If the bottom surface BS of the liquid storage module 100 is concavely formed, all the liquid LQ stored in the liquid storage module 100 may be transformed into droplets DR while gathering in the concave portion, and then the droplets DR may fall. The bottom surface BS of the liquid storage module 100 may be formed to be inclined in one direction. In this structure, because the liquid LQ gathers on one side along the inclined bottom surface BS, most of the liquid LQ may be transformed into droplets DR, and then the droplets DR may fall. At least one nozzle 210 may be connected to the lowest portion of the concave bottom surface BS of the liquid storage module 100.

The bottom surface BS and the wall surface of the liquid storage module 100 may be coated with a hydrophobic material. The hydrophobic material coated on the bottom surface BS and the wall surface of the liquid storage module 100 may allow a larger amount of liquid LQ (e.g., water) stored in the liquid storage module 100 to flow toward the concave portion of the bottom surface BS.

The nozzles 210 of the droplet formation module 200 may be connected to the bottom surface BS of the liquid storage module 100, so the liquid LQ stored in the liquid storage module 100 may flow to the nozzles 210. When the droplets DR formed by the nozzles 210 fall to the energy conversion devices 310, if the droplets DR fall to some of the energy conversion devices 310 from a relatively high position and fall to the other energy conversion devices 310 from a relatively low position, the degrees of deterioration of the energy conversion devices 310 may differ from each other. If the degrees of deterioration of the energy conversion devices 310 differ from each other, that is, if the degrees of deterioration of some energy conversion devices 310 are relatively high and the degrees of deterioration of the other energy conversion devices 310 are relatively low, the capacity output from the energy conversion module 300 may be reduced. Therefore, the energy conversion module 300 needs to be replaced.

If the degrees of deterioration of the plurality of energy conversion devices 310 included in the energy conversion module 300 are adjusted to be substantially identical to each other, the lifespan of the energy conversion module 300 may be maximized. In order to allow the energy conversion devices 310 to uniformly deteriorate, the heights from which the droplets DR fall need to be substantially identical. Therefore, in the droplet formation mode 200 according to the embodiment, the end points EE of the nozzles 210 may be located at the same height H1. In order to allow the end points EE of the nozzles 210 to be located at the same height, a nozzle 210e connected to a concave portion of the bottom surface BS may be formed to have a relatively short length, and a nozzle 210f connected to a high portion of the bottom surface BS may be formed to have a relatively long length.

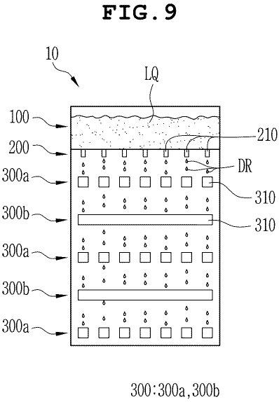

FIG. 9 is a view showing an energy conversion module 300 in which the energy conversion devices 310 are provided in an independent form and an energy conversion module 300 in which the energy conversion devices 310 are provided in an integrated form according to an embodiment.

The energy conversion block 10 according to an embodiment may include one or more energy conversion modules selected from among an independent-type energy conversion module 300a in which the plurality of energy conversion devices 310 outputs electrical energy independently and an integrated-type energy conversion module 300b in which the plurality of energy conversion devices 310 is integrated with each other to output electrical energy.

The independent-type energy conversion module 300a is a module in which the plurality of energy conversion devices 310 is disposed so as to output electrical energy independently. The integrated-type energy conversion module 300b is a module in which the plurality of energy conversion devices 310 is integrated with each other so that the electrical energy is output through a single wire.

A portion of the energy conversion module 300 may be formed in an independent type, and the other portion of the energy conversion module 300 may be formed in an integrated type. The energy conversion block 10 may be structured such that the independent-type energy conversion module 300a and the integrated-type energy conversion module 300b are stacked vertically. The energy conversion block 10 may include a plurality of independent-type energy conversion modules 300a and a plurality of integrated-type energy conversion modules 300b.

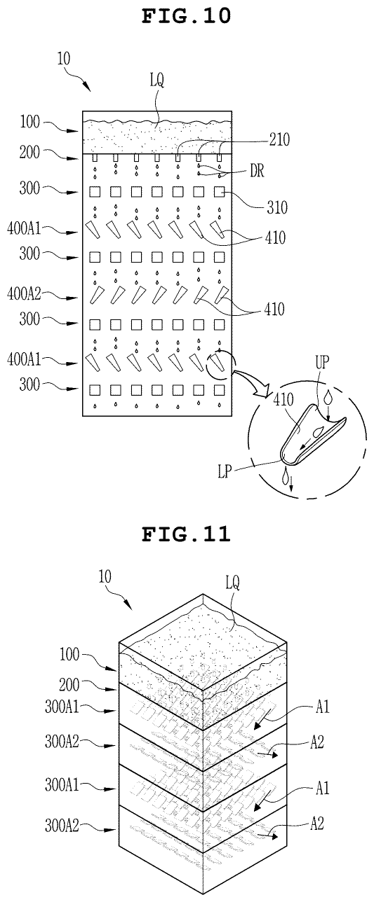

FIG. 10 is a view showing a droplet guide module 400 according to an embodiment.

The continuous energy generation apparatus using liquid LQ according to the embodiment may further include a droplet guide module 400, which is disposed between the plurality of energy conversion modules 300 stacked vertically in order to guide the direction of the droplets DR falling from the energy conversion module 300.

If the energy conversion devices 310 of the energy conversion module 300 are disposed only in one direction, the droplets DR may continue to move in one direction, and may not fall on one side of the energy conversion module 300. The droplet guide module 400 may guide the droplets DR having passed through the energy conversion device 310 disposed thereabove to move to the energy conversion device 310 disposed directly therebelow or an adjacent energy conversion device 310.

The droplet guide module 400 may include a plurality of guide plates 410 capable of guiding the droplets DR. The guide plates 410 may be disposed corresponding to the end points EE of the energy conversion devices 310 of the energy conversion module 300 located above the droplet guide module 400. In order to guide the droplets DR, the guide plates 410 may be disposed corresponding to the start points SE of the energy conversion devices 310 of the energy conversion module 300 located below the droplet guide module 400. The upper portions UP of the guide plates 410 may be disposed so as to receive the droplets DR falling from above, and the lower portions LP of the guide plates 410 may be disposed so as to drop the droplets DR to the energy conversion devices 310 located therebelow.

The guide plate 410 may be disposed in an inclined form in order to guide the position of the falling droplet DR in a desired direction. The guide plate 410 may be formed such that the upper portion UP thereof is relatively wide and the lower portion LP thereof is relatively narrow. The surface of the guide plate 410 may be coated with a hydrophobic material. The guide plate 410 may be disposed in an inclined form so that the upper portion UP thereof is located at a higher position and the lower portion LP thereof is located at a lower position.

The droplet guide module 400 may be formed, based on the placement of the energy conversion device 310 of the energy conversion module 300 disposed thereabove and the placement of the energy conversion device 310 of the energy conversion module 300 disposed therebelow, to guide the droplet DR falling from the end point EE of the upper energy conversion device 310 to fall to the start point SE of the lower energy conversion device 310.

The droplet guide module 400 may include guide plates 410 that are disposed in various forms in accordance with the placement of the energy conversion device 310 of the upper energy conversion module 300 and the placement of the energy conversion device 310 of the lower energy conversion module 300.

The droplet guide module 400 may include a first droplet guide module 400A1 formed to guide the droplet DR in a first direction A1 and a second droplet guide module 400A2 formed to guide the droplet DR in a second direction A2. The first droplet guide module 400A1 and the second droplet guide module 400A2 may be alternately disposed. The first direction A1 and the second direction A2 may be opposite each other. The first droplet guide module 400A1 may move the droplet DR in the first direction A1 so that the droplet DR passes through the energy conversion module 300, and then the second droplet guide module 400A2 may move the droplet DR in the second direction A2 so that the droplet DR passes through the energy conversion module 300. This process may be repeatedly performed. In such a structure, the droplet DR may fall in a generally vertical direction along the zigzag path.

Meanwhile, the energy conversion module 300 that causes the droplet DR to flow in the first direction A1 and the droplet guide module 400 that causes the droplet DR to flow in the second direction A2 may be alternately stacked. In this case, the droplet DR may move in the opposite direction along the guide plate 410 by the same distance as a distance by which the droplet DR moves along the energy conversion device 310. Thus, the arrangement of the energy conversion devices 310 of the plurality of energy conversion modules 300 may be identical to each other, and the arrangement of the guide plates 410 of the plurality of droplet guide modules 400 may be identical to each other.

FIG. 11 is a view showing an energy conversion module 300 in which the direction of the energy conversion device 310 is adjusted according to an embodiment.

A plurality of energy conversion modules 300 may be disposed such that the direction of an energy conversion device 310 disposed at a higher position and the direction of an energy conversion device 310 disposed at a lower position are opposite each other, whereby the droplet DR falling from the end point EE of the energy conversion device 310 disposed at a higher position may fall to the start point SE of the energy conversion device 310 disposed at a lower position.

The plurality of energy conversion modules 300 may include a first orientation energy conversion module 300A1 in which an energy conversion device 310 is disposed so that a droplet DR falls in the first direction A1 and a second orientation energy conversion module 300A2 in which an energy conversion device 310 is disposed so that a droplet DR falls in the second direction A2. Because the first orientation energy conversion module 300A1 and the second orientation energy conversion module 300A2 cause the droplet DR to flow in the first direction A1 and the second direction A2, respectively, if the first orientation energy conversion module 300A1 and the second orientation energy conversion module 300A2 are alternately stacked, the droplet DR may fall in a generally vertical direction along the zigzag path.

In the structure in which the first orientation energy conversion module 300A1 and the second orientation energy conversion module 300A2 are alternately disposed, the energy conversion block 10 may not include the droplet guide module 400.

According to the present disclosure described above, energy output discretely from the energy conversion module 300 may be collected and converted into a continuous flow of energy, and then the continuous flow of energy may be supplied to the load 30 or stored in the battery 40. Further, one falling droplet DR may enable production of energy multiple times while passing through the plurality of energy conversion devices 310. Accordingly, energy may be efficiently produced using the droplet DR.

As is apparent from the above description, according to an embodiment of the present disclosure, energy output discretely from an energy conversion module may be collected and converted into a continuous flow of energy, and then the continuous flow of energy may be supplied to a load or stored in a battery.

According to an embodiment of the present disclosure, because one falling droplet enables production of energy multiple times while passing through a plurality of energy conversion devices, energy may be efficiently produced using the droplet.

Although preferred embodiments of the present disclosure have been illustrated and described in order to exemplify the principle of the present disclosure, the present disclosure is not limited to the specific embodiments. It will be understood that various modifications and changes can be made by those skilled in the art without departing from the spirit and scope of the disclosure as defined by the appended claims.

What is claimed is:

1. A continuous energy generation apparatus using liquid, the continuous energy generation apparatus comprising an energy conversion block comprising:
a liquid storage module configured to at least temporarily store liquid;
a droplet formation module provided with a plurality of nozzles to transform the liquid stored in the liquid storage module into droplets and drop the droplets; and
an energy conversion module provided with a plurality of energy conversion devices to output electrical energy through contact with the falling droplets.

2. The continuous energy generation apparatus according to claim 1, further comprising a plurality of energy conversion blocks, each comprising the liquid storage module, the droplet formation module, and the energy conversion module grouped into a block,
wherein the plurality of energy conversion blocks is stacked vertically so that the droplets used in the energy conversion module of an upper energy conversion block enters the liquid storage module of a lower energy conversion block.

3. The continuous energy generation apparatus according to claim 1, further comprising an energy collection unit configured to receive electrical energy output from the plurality of energy conversion devices, convert a discrete flow of energy output from the plurality of energy conversion devices into a continuous flow of energy, and supply the continuous flow of energy to a battery or a load.

4. The continuous energy generation apparatus according to claim 1, wherein the energy conversion block comprises a plurality of energy conversion modules stacked vertically, and
wherein the droplets used in an energy conversion module located at a higher position fall to an energy conversion module located at a lower position and are used again to generate energy.

5. The continuous energy generation apparatus according to claim 1, wherein the energy conversion block is configured such that one or more energy conversion modules selected from among a first capacity energy conversion module configured to generate output of a first capacity and a second capacity energy conversion module configured to generate output of a second capacity are stacked vertically, thereby meeting an energy output requirement.

6. The continuous energy generation apparatus according to claim 1, wherein the droplet formation module comprises one or more nozzles selected from among a first nozzle configured to form a droplet having a first size and a second nozzle configured to form a droplet having a second size.

7. The continuous energy generation apparatus according to claim 1, wherein the liquid storage module comprises a bottom surface at least partially concavely formed, and
wherein, among the plurality of nozzles of the droplet formation module, a nozzle connected to a concave portion of the liquid storage module is formed to have a relatively short length, and a nozzle connected to another portion of the liquid storage module is formed to have a relatively long length, whereby tips of the plurality of nozzles are located on a same line.

8. The continuous energy generation apparatus according to claim 1, wherein the energy conversion block comprises one or more energy conversion modules selected from among an independent-type energy conversion module configured such that the plurality of energy conversion devices outputs electrical energy independently and an integrated-type energy conversion module configured such that the plurality of energy conversion devices is integrated with each other to output electrical energy.

9. The continuous energy generation apparatus according to claim 4, further comprising a droplet guide module disposed between the plurality of energy conversion modules stacked vertically to guide a direction of the droplets falling from the energy conversion module.

10. The continuous energy generation apparatus according to claim 9, wherein the droplet guide module is formed, based on placement of the energy conversion devices of an energy conversion module disposed thereabove and placement of the energy conversion devices of an energy conversion module disposed therebelow, to guide the droplets falling from end points of upper energy conversion devices to fall to start points of lower energy conversion devices.

11. The continuous energy generation apparatus according to claim 4, wherein the droplet guide module comprises:
a first droplet guide module formed to guide the droplets in a first direction; and
a second droplet guide module formed to guide the droplets in a second direction, and
wherein the first droplet guide module and the second droplet guide module are alternately disposed.

12. The continuous energy generation apparatus according to claim 4, wherein the plurality of energy conversion modules is disposed such that a direction of energy conversion devices disposed at a higher position and a direction of energy conversion devices disposed at a lower position are opposite each other so that droplets falling from end points of the energy conversion devices disposed at a higher position fall to start points of the energy conversion devices disposed at a lower position.
